(19) United States
(12) Patent Application Publication
(10) Pub. No.: US 2012/0025223 A1
(43) Pub. Date: Feb. 2, 2012

(54) LED LIGHTING DEVICE WITH HIGH COLOUR RE-PRODUCIBILITY

(76) Inventors: Tek Beng Low, Melaka (MY); Eng Wah Tan, Melaka (MY); Chee Sheng Lim, Melaka (MY)

(21) Appl. No.: 13/152,771

(22) Filed: Jun. 3, 2011

(30) Foreign Application Priority Data
Jun. 7, 2010 (MY) PI 2010002619

(51) Int. Cl. H01L 33/44

(52) U.S. Cl. 257/89; 257/E33.061

(57) ABSTRACT

The invention relates to a light emitting diode (LED) lighting device that is comprised of a plurality of LED components and is characterized by the mixture of; a first group of light source provided by blue LEDs mixed with luminescence conversion element and the blue light has a dominant wavelength in the range from 430 nm to 460 nm and the luminescence conversion element absorbs a portion of this blue light and converts to a secondary light have a peak wavelength in the range of 520 nm to 545 nm; a second group of light source provided by LEDs with dominant wavelength in the range of 600 nm to 610 nm and a third group of light source provided by LEDs with dominant wavelength in the range of 615 nm to 625 nm to produce mixture of light that has good color re-producibility.

### 1. FIELD OF INVENTION

The invention relates to a light emitting diode (LED) lighting device that is comprised of a plurality of LED components and is characterized by the mixture of a primary light source, a secondary light source and a third light source to produce a final mixture of light that has good color re-producibility and has color coordinates along or close to the Planckian black body line.

### 2. PRIOR ART

Optoelectronic components such as LED are widely used in the world today especially for lighting and signaling devices. Conventional LED naturally are capable of generating saturated colours ranging from long wavelength such as red to shorter wavelength such as blue at the other end of the spectrum; depending on the semiconductor material used to manufacture the LED chip. GaP and AlInGaP material are commonly used to generate colours in the red, orange and yellow spectrum. As for blue, GaN and InGaN are used instead. These saturated colours can also be mixed in order to generate a wide range of colours. For instance, red, green and blue can be mixed in certain proportion to generate white. This technique was described in many prior arts.

As LED application expands, there is a demand for an even wider range of colours especially colours with coordinates along or close to the Planckian black body line. This is important as majority of today's light sources are emitting light in this colour region. In addition, these light sources also provide light with very good colour re-producibility characteristics.

One approach to fulfill this need is to employ a luminescence conversion element.

Such method is described by Hohn et al. in U.S. Pat. No. 6,066,861. The prior art described the method where a luminescence conversion element is used to convert a portion of a primary wavelength emitted by a semiconductor body into radiation of a longer wavelength. This makes it possible to produce a component which radiates polychromatic light, in particular white light, with a single light-emitting semiconductor chip. With the correct primary light source and selection of luminescence conversion element, a final mixture of light with colour coordinates along or close to the Planckian black body line can be produced.

However, these methods may not produce a light with good color re-producibility properties. Color rendering index (CRI) is typically used to measure the color re-producibility of a light source. CRI is a relative measurement of how the color rendition of an illumination system compares to that of a blackbody radiator. An ideal light source would have a CRI of 100. Such light source is always preferred. Daylight for example has a highest CRI of 100 while fluorescent lamps have a CRI in the range of 70-80.

Typical blue LEDs mixed with luminescence conversion element on the other hand will only exhibit CRI in the range of 60-75. For typical illumination applications, a CRI of 75-90 is required to ensure comfort to the human sight and optimum color re-producibility. There are numerous portions of color component that are not present in the converted output radiation especially in the higher wavelength region; ranging from 600 nm to 700 nm. As a result, one of the methods to improve color rendering of blue LEDs mixed with luminescence conversion element is to include red LEDs as the secondary light source in the lighting device. This method is described in U.S. Pat. No. 7,213,940.

U.S. Pat. No. 7,213,940 describes a lighting device comprising first and second groups of solid state light emitters, which emit light having dominant wavelength in ranges of from 430 nm to 480 nm and from 600 nm to 630 nm, respectively; and a first group of lumiphors which emit light having dominant wavelength in the range of from 555 nm to 585 nm. This particular range of lumiphors is also generally termed as yellow green lumiphors due to the colour of the light emitted. Materials that can be used to produce such lumiphors include yttrium aluminium garnet (YAG), terbium aluminium garnet (TAG), etc.

This patent will try to describe an alternative method to generate a mixture of light with equally good colour re-producibility characteristics.

### 3. DESCRIPTION OF DRAWINGS

The drawings enclosed are as follows:

FIG. 1 is the CIE color chart depicting the Planckian blackbody line;

FIG. 2 is the typical color spectrum of a blue LEDs mixed with luminescence conversion element ;

FIG. 3 illustrates a typical diagram of the emission spectrum of the luminescence conversion element.

FIG. 4 illustrates a typical diagram of the colour spectrum of the mixed light from the blue LEDs and emission by the luminescence conversion element;

FIG. 5 illustrates a typical diagram of the colour spectrum of the mixed light from the lighting device;

FIG. 6 is the schematic view of the first exemplary embodiment of a LED light bulb according to the invention;

FIG. 7 is the schematic view of the first exemplary embodiment of the components and PCB according to the invention.

### 4. DETAIL DESCRIPTION

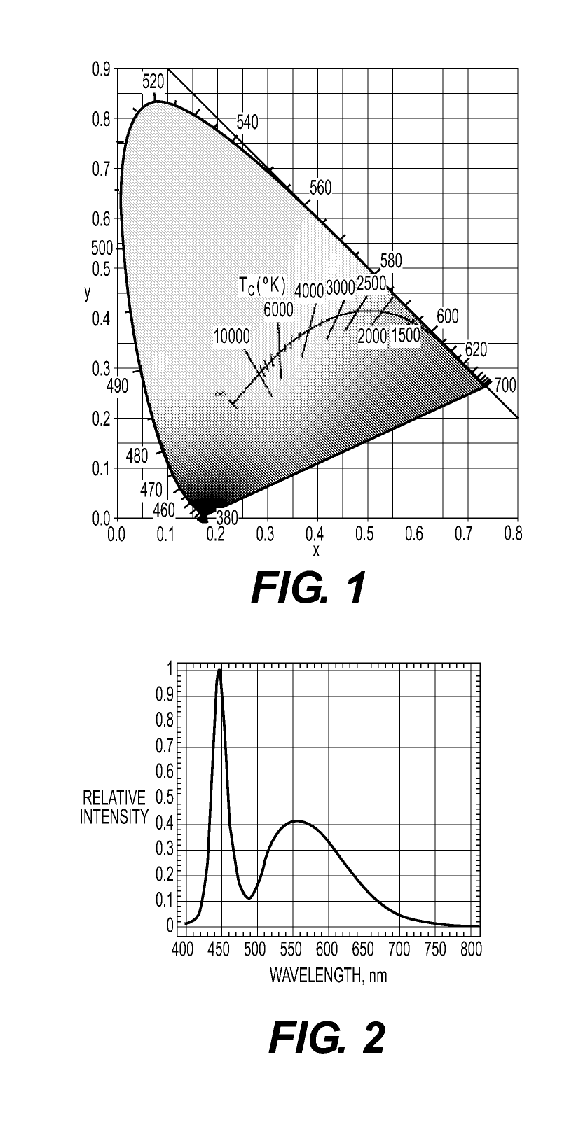

The invention relates to a light emitting diode (LED) lighting device that is comprised of a plurality of LED components and is characterized by the mixture of a primary light source, a secondary light source and a third light source to produce a final mixture of light that has good color re-producibility and has color coordinates along or close to the Planckian black body line as shown in FIG. 1.

Blue LEDs mixed with luminescence conversion element is typically used as the primary light source for most of the LED lighting device today. Such light source is capable to generate colors with color coordinates along or close to the Planckian black body line. A typical color spectrum of such a light source is as shown in FIG. 2. Although such light source is able to produce the desirable color for most applications; the color re-producibility of such light source is normally below expectation.

In accordance to the present invention, a light emitting diode (LED) lighting device with good color re-producibility is comprised of a plurality of LED components and is characterized by the mixture of; a first group of light source provided by blue LEDs mixed with luminescence conversion element and the blue light has a dominant wavelength in the range from 430 nm to 460 nm and the luminescence conversion element absorbs a portion of this blue light and converts to a secondary light having a peak wavelength in the range of 520 nm to 545 nm; a second group of light source provided by LEDs with dominant wavelength in the range of 600 nm to 610 nm and a third group of light source provided by LEDs with dominant wavelength in the range of 615 nm to 625 nm.

The first group of light source is provided by blue LEDs mixed with luminescence conversion element. The blue LED can be made out of a nitride compound semiconductor such as InGaN or GaN doped with other impurities. The blue LEDs are selected such that the emitted wavelength is suitable for absorption by the luminescence conversion element. In accordance to the present invention, the blue LEDs have a dominant wavelength in the range from 430 nm to 460 nm and the luminescence conversion element will absorb a portion of this blue light and converts to a secondary light having a peak wavelength in the range of 520 nm to 545 nm.

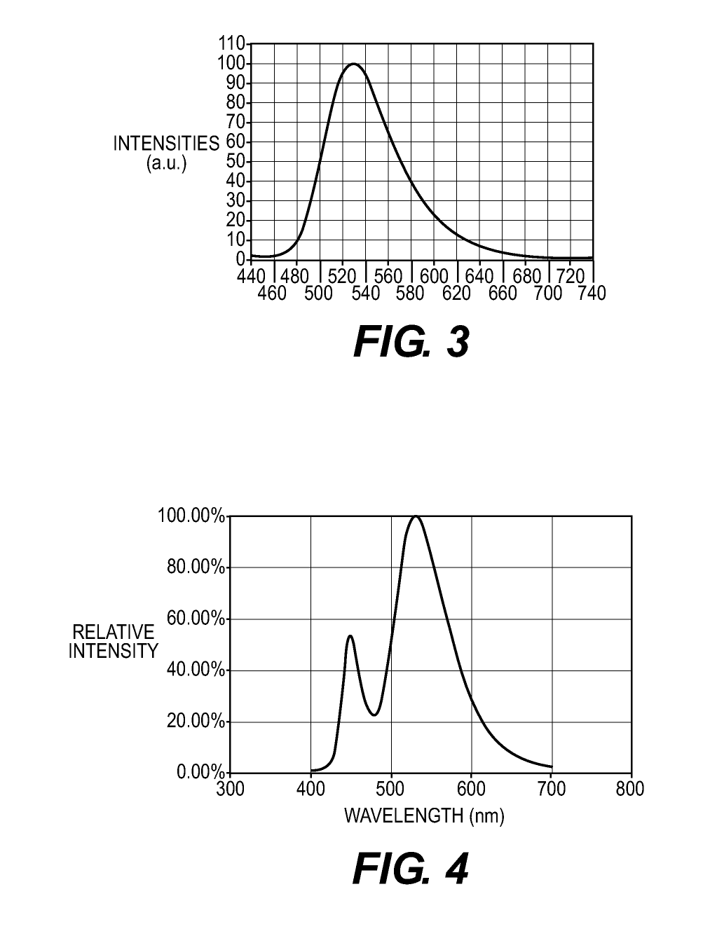

A typical emission spectrum of such a luminescence conversion element is as shown in FIG. 3. Such a luminescence conversion element would absorb a portion of the blue light and will subsequently emit a secondary light having a peak wavelength in the range of 520 nm to 545 nm. The secondary emission will have a typical half power band-width of about 60 nm to 100 nm. Such luminescence conversion element is also commonly known as green phosphor due to the color emitted by the phosphor. Typical material composition of such luminescence conversion element includes silicates activated by europium and rare earth garnets activated by cerium. These materials are very efficient in light conversion compared to others because the emitted wavelengths are in the region where the human eye has the highest sensitivity.

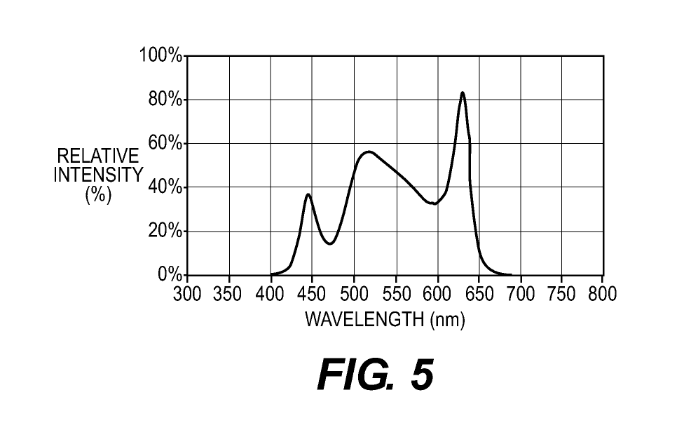

The mixed light from the blue LEDs and emission by the luminescence conversion element would have a typical colour spectrum as shown in FIG. 4. The colour of the mixed light when observed would have a very strong green hue and is certainly not suitable for general illumination applications. In order to generate white light with color coordinates along or close to the Planckian black body line and suitable for general illumination, another 2 groups of light source will be needed. The second group of light source provided by LEDs should have a dominant wavelength in the range of 600 nm to 610 nm and a third group of light source provided by LEDs with dominant wavelength in the range of 615 nm to 625 nm. Both these two groups of LEDs can be made from compound semiconductor material such as AlInGaP and GaP. The proportion of mixture in terms of light output between the three groups of light source is typically in the range of 55%-75%, 10%-20% and 20%-30% respectively. With this mixture, a white light with color coordinates along or close to the Planckian black body line would be produced. By varying the colour spectrum or wavelength of the three light sources and the mixing proportion of each group, the colour coordinate of the final mix can be varied along the Planckian black body line. The typical colour spectrum of the final mixed light is as illustrated in FIG. 5. Such a light source will generate good colour rendering capability and has typical CRI in the range of 75-90. This range of CRI is suitable for general illumination applications.

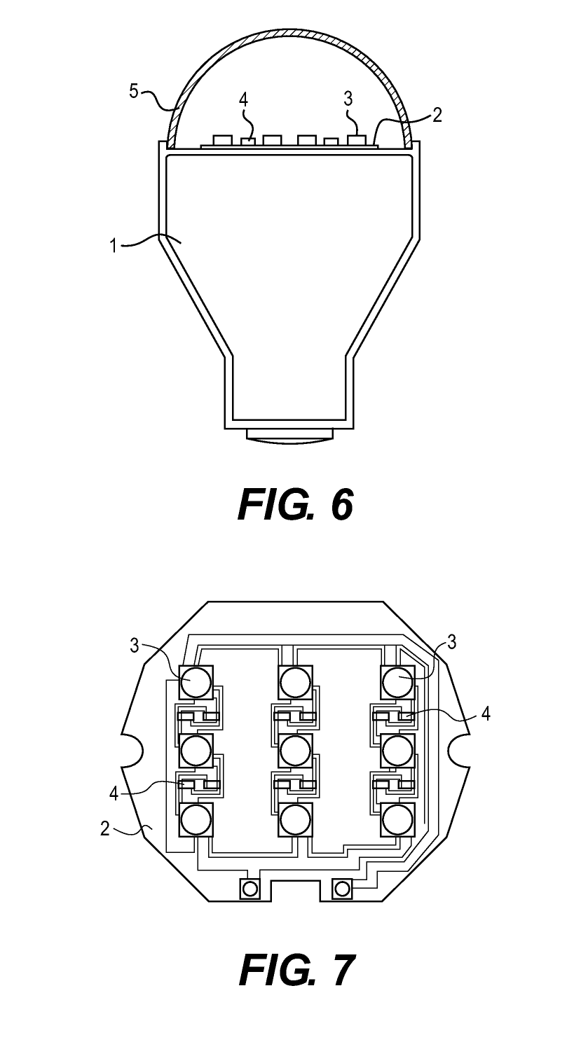

In an embodiment of the present invention, FIG. 6 is a schematic view of the first exemplary embodiment of a LED light bulb according to the invention. The LED light bulb is made up of an external casing (1). This casing can be made out of metal such as aluminium or cast iron. It can also be molded out of conventional plastic such as ABS. The light sources are assembled on a PCB (2). FIG. 7 illustrates a typical lay-out of the PCB where the light sources are mounted. A group of blue LEDs mixed with luminescence conversion element (3) is typically used as the primary light source. The blue LEDs have a dominant wavelength in the range from 430 nm to 460 nm and the luminescence conversion element will absorb a portion of this blue light and converts to a secondary light having a peak wavelength in the range of 520 nm to 545 nm. This group of light source will typically generate a high level of total light output in the range of 400 lumen to 1000 lumen. A multiple of this light source is arranged in an electrical circuit arrangement so that electrical connection can be made. In the matrix of the primary light source, LEDs with dominant wavelength of 615 nm to 625 nm and 600 nm to 610 nm are added as secondary light sources (4) into the electrical circuit arrangement so that the color rendering index (CRI) of the light can be improved. The secondary light source will supply typically about 25% to 40% of the primary light source. In this proportion of mixing, the white light generated will have color coordinates along or close to the Planckian black body line. The CR1 of the lighting device would also be approximately in the range of 75-90.

1. A light emitting diode (LED) lighting device with good color re-producibility is comprised of a plurality of LED components and is characterized by the mixture of;
a first group of light source provided by blue LEDs mixed with luminescence conversion element and the blue light has a dominant wavelength in the range from 430 nm to 460 nm and the luminescence conversion element absorbs a portion of this blue light and converts to a secondary light having a peak wavelength in the range of 520 nm to 545 nm;
a second group of light source provided by LEDs with dominant wavelength in the range of 600 nm to 610 nm and;
a third group of light source provided by LEDs with dominant wavelength in the range of 615 nm to 625 nm.

2. A lighting device as stated in claim 1, where the colour of the mixed light has color coordinates along or close to the Planckian black body line.

3. A lighting device as stated in claim 1, where the proportion of mixture in terms of light output between the three groups of light source; is typically in the range of 55%-75%, 10%-20% and 20%-30% respectively.

4. A lighting device as stated in claim 1, where the color rendering index is in the range of 75-90.
